(19) United States
(12) Patent Application Publication
(10) Pub. No.: US 2013/0082697 A1
(43) Pub. Date: Apr. 4, 2013

(54) MAGNETORESISTANCE SENSING DEVICE AND MAGNETORESISTANCE SENSOR INCLUDING SAME

(71) Applicants: NAI-CHUNG FU, Taoyuan County (TW); KUANG-CHING CHEN, Changhua County (TW); FU-TAI LIOU, Hsinchu County (TW)

(72) Inventors: NAI-CHUNG FU, Taoyuan County (TW); KUANG-CHING CHEN, Changhua County (TW); FU-TAI LIOU, Hsinchu County (TW)

(73) Assignee: Voltafield Technology Corporation, Jhubei City (TW)

(21) Appl. No.: 13/337,147

(22) Filed: Dec. 25, 2011

(30) Foreign Application Priority Data
Sep. 29, 2011 (TW) 100135263

(51) Int. Cl. G01R 33/09

(52) U.S. Cl. 324/252

(57) ABSTRACT

A magnetoresistance sensing device includes a substrate, a magnetoresistance sensing unit, and a magnetic field adjusting unit. In response to a first external magnetic field horizontal to a surface of the substrate, the magnetoresistance sensing unit results in a change of an electrical resistance. The magnetic field adjusting unit is used for changing a direction of a second external magnetic field vertical to the surface of the substrate to be consistent with the first external magnetic field, so that the magnetoresistance sensing unit results in a change of the electrical resistance in response to the second external magnetic field. A magnetoresistance sensor includes four magnetoresistance sensing devices, which are arranged in a Wheatstone bridge. An output voltage of the Wheatstone bridge is not altered as the first external magnetic field is changed, but the output voltage of the Wheatstone bridge is altered as the second external magnetic field is changed.

### FIELD OF THE INVENTION

The present invention relates to a magnetoresistance sensing device, and particularly to a magnetoresistance sensing device for detecting the magnitude and direction of a magnetic field vertical to a surface of a substrate. The present invention also relates to a magnetoresistance sensor including such a magnetoresistance sensing device.

### BACKGROUND OF THE INVENTION

FIG. 1 is a schematic cross-sectional view illustrating a conventional single-axis magnetoresistance sensing device. A magnetoresistance sensor including the single-axis magnetoresistance sensing device may be used to precisely detect the magnitude and direction of a magnetic field horizontal to a surface of a substrate in a space. The single-axis magnetoresistance sensing device comprises an insulating substrate 10, a magnetoresistive layer 12 and a conductive structure 14. The conductive structure 14 comprises a plurality of barber-pole conductors. The barber-pole conductors can facilitate a direction change of current flow inside the magnetoresistive layer 12, thereby increasing the sensitivity of the magnetoresistance sensing device. The conductive structure 14 may be disposed over or under the magnetoresistive layer 12.

FIG. 2 is a schematic top view illustrating the magnetoresistance sensing device of FIG. 1. As shown in FIG. 2, an angle between the lengthwise extending direction of the conductive structure 14 and the lengthwise extending direction of the magnetoresistive layer 12 is about 45 degrees. Moreover, the conductive structure 14 is electrically connected with the magnetoresistive layer 12 to form barber-pole conductors.

FIG. 3 is a schematic circuit diagram illustrating a magnetoresistance sensor including four conventional magnetoresistance sensing devices. As shown in FIG. 3, four magnetoresistance sensing devices 31, 32, 33 and 34 that have barber-pole conductors are disposed on a substrate (not shown) and electrically connected with each other to form a Wheatstone bridge. The magnetoresistance sensing devices 31 and 33 are classified into a first group. The magnetoresistance sensing devices 32 and 34 are classified into a second group. Since the lengthwise extending direction of the barber-pole conductors in the first group is different from that in the second group, when the four magnetoresistance sensing devices have the same magnetization direction (e.g. in the direction indicated as the arrow M), only the magnitude of the magnetic field in a direction H horizontal to the substrate can be sensed by reading the voltage value of a voltmeter 35. However, as shown in FIG. 4, the magnitude of the magnetic field in a direction ⊙ vertical to the substrate fails to be sensed by reading the voltage value of the voltmeter 35. Under this circumstance, the voltage value is unchanged.

Due to the limitation of the manufacturing processes and configurations, the magnetoresistance sensing device formed on the substrate and the magnetoresistance sensor including the magnetoresistance sensing device are only able to sense the change of the magnetic field horizontal to the substrate surface but unable to sense the change of the magnetic field vertical to the substrate surface. For sensing the magnetic field in the three-dimensional space, it is necessary to combine at least two orthogonal substrates together. Under this circumstance, the applications of the magnetoresistance sensing device and the magnetoresistance sensor are restricted.

### SUMMARY OF THE INVENTION

An aspect of present invention provides a magnetoresistance sensing device. The magnetoresistance sensing device includes a substrate, a magnetoresistance sensing unit, and a magnetic field adjusting unit. The magnetoresistance sensing unit is formed over the substrate. In response to a first external magnetic field horizontal to a surface of the substrate, the magnetoresistance sensing unit results in a change of an electrical resistance. The magnetic field adjusting unit is formed over the substrate for changing a direction of a second external magnetic field vertical to the surface of the substrate to be consistent with the first external magnetic field, so that the magnetoresistance sensing unit results in a change of the electrical resistance in response to the second external magnetic field.

In an embodiment, the magnetoresistance sensing unit includes a horizontal component magnetoresistance structure and a conductive structure. The horizontal component magnetoresistance structure is formed over the substrate. The conductive structure is formed over the substrate for changing a direction of a current flowing through the horizontal component magnetoresistance structure, so that the horizontal component magnetoresistance structure results in a linear change of the electrical resistance in response to the first external magnetic field. Moreover, an angle between a lengthwise extending direction of the conductive structure and a lengthwise extending direction of the horizontal component magnetoresistance structure is greater than 0 degree and smaller than 90 degrees.

In an embodiment, the conductive structure is disposed over the conductive structure.

In an embodiment, the conductive structure is disposed under the conductive structure.

In an embodiment, the magnetic field adjusting unit is a vertical component magnetoresistance structure. The horizontal component magnetoresistance structure and the vertical component magnetoresistance structure are collaboratively defined as a three-dimensional magnetoresistance structure.

In an embodiment, the vertical component magnetoresistance structure is formed on inner walls of one or more trench structures in the substrate.

In an embodiment, the vertical component magnetoresistance structure is formed on outer walls of one or more raised structures on the substrate.

In an embodiment, the vertical component magnetoresistance structure is formed on two sidewalls of a stepped structure of the substrate.

In an embodiment, the magnetic field adjusting unit is a magnetic flux conducting structure for changing magnetic field distribution in the space, thereby concentrating a magnetic flux of the second external magnetic field and guiding the magnetic flux in a direction consistent with the first external magnetic field.

Another aspect of present invention provides magnetoresistance sensor. The magnetoresistance sensor includes four magnetoresistance sensing devices of the present invention. The four magnetoresistance sensing devices are arranged in a Wheatstone bridge and includes a first magnetoresistance sensing device, a second magnetoresistance sensing device, a third magnetoresistance sensing device and a fourth magnetoresistance sensing device. Each of the second magnetoresistance sensing device and the fourth magnetoresistance sensing device is connected to both of the first magnetoresistance sensing device and the third magnetoresistance sensing device. An output voltage of the Wheatstone bridge is not altered as the first external magnetic field is changed, but the output voltage of the Wheatstone bridge is altered as the second external magnetic field is changed.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic cross-sectional view illustrating a conventional single-axis magnetoresistance sensing device;

FIG. 2 is a schematic top view illustrating the magnetoresistance sensing device of FIG. 1;

FIGS. 3 and 4 are schematic circuit diagrams illustrating a magnetoresistance sensor including four conventional magnetoresistance sensing devices;

FIGS. 5A and 5B schematically illustrate a magnetoresistance sensing device according to a first embodiment of the present invention;

FIGS. 6A and 6B schematically illustrate a magnetoresistance sensing device according to a second embodiment of the present invention;

FIGS. 7A and 7B schematically illustrate two variant examples of the vertical component magnetoresistance structure used in the magnetoresistance sensing device of the present invention;

FIGS. 8A and 8B are schematic circuit diagrams illustrating a magnetoresistance sensor including four magnetoresistance sensing devices according to an embodiment of the present invention;

FIGS. 9A and 9B schematically illustrate a magnetoresistance sensing device according to a third embodiment of the present invention;

FIGS. 9C and 9D are schematic circuit diagrams illustrating a magnetoresistance sensor including four magnetoresistance sensing devices as shown in FIGS. 9A and 9B;

FIGS. 10A and 10B schematically illustrate a magnetoresistance sensing device according to a fourth embodiment of the present invention;

FIGS. 11A and 11B are schematic circuit diagrams illustrating a magnetoresistance sensor including four magnetoresistance sensing devices as shown in FIGS. 10A and 10B;

FIGS. 12A and 12B schematically illustrate a semiconductor manufacturing method of the magnetoresistance sensing device according to an embodiment of the present invention.

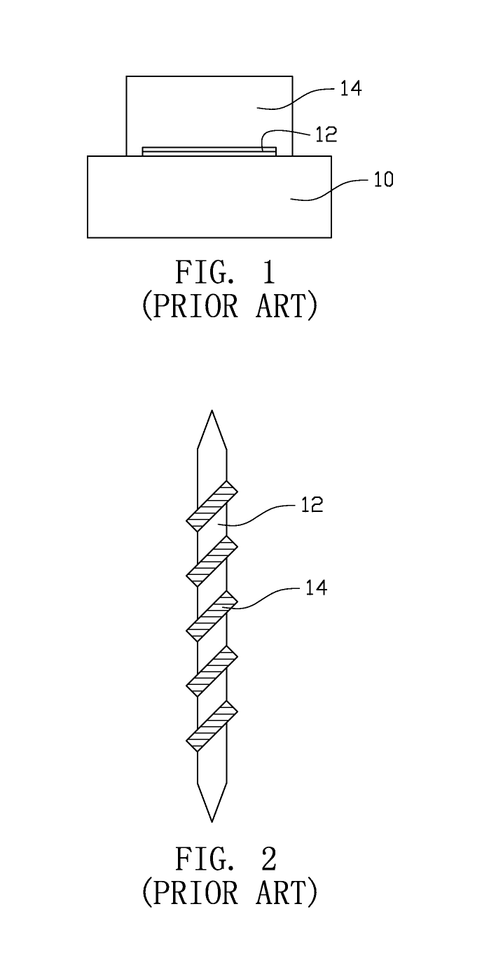

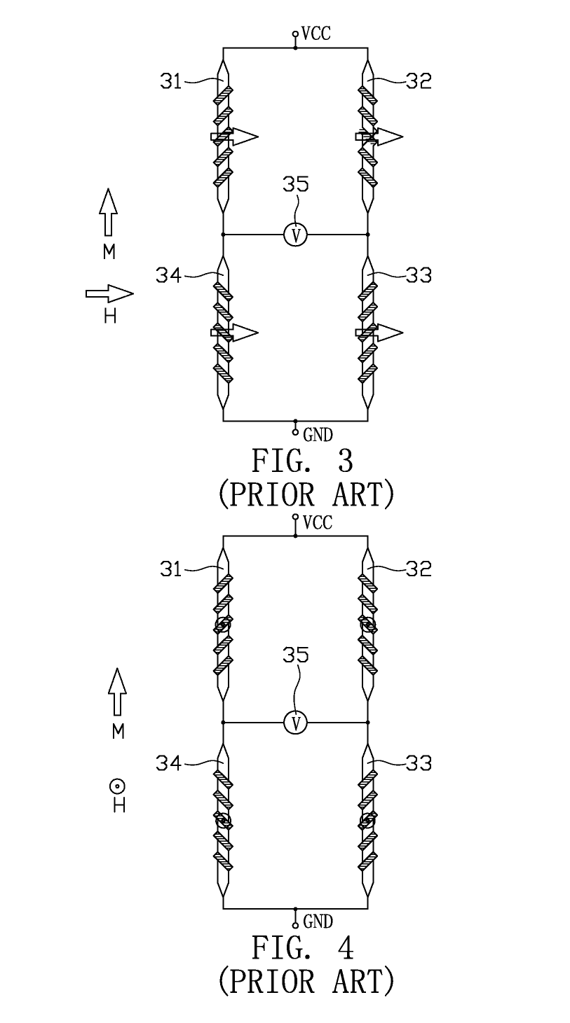

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

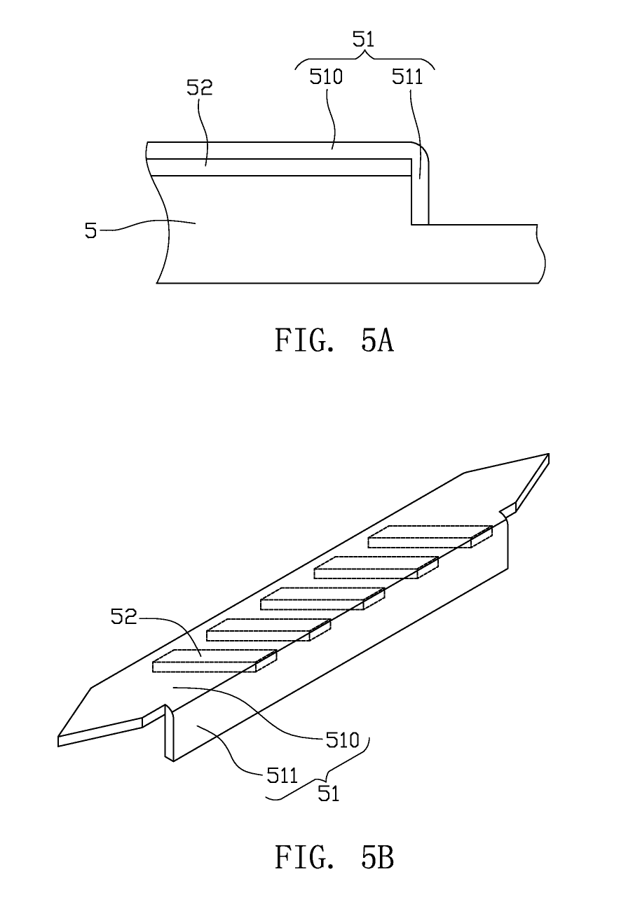

Please refer to FIGS. 5A and 5B, which schematically illustrate a magnetoresistance sensing device according to an embodiment of the present invention. The magnetoresistance sensing device is capable of sensing the magnitude of a magnetic field in a direction vertical to the surface of the substrate in a three-dimensional space. FIG. 5A is a cross-sectional view of the magnetoresistance sensing device. As shown in FIG. 5A, the magnetoresistance sensing device is formed on a substrate 5, and comprises a three-dimensional magnetoresistance structure 51 and a conductive structure 52. The three-dimensional magnetoresistance structure 51 comprises a horizontal component magnetoresistance structure 510 and a vertical component magnetoresistance structure 511. The horizontal component magnetoresistance structure 510 and the vertical component magnetoresistance structure 511 are connected with each other. The conductive structure 52 comprises a plurality of barber-pole conductors, which are disposed over or under the horizontal component magnetoresistance structure 510 at a specified angle. In this embodiment, the conductive structure 52 is disposed under the horizontal component magnetoresistance structure 510. FIG. 5B is a schematic perspective view of the magnetoresistance sensing device. Due to the vertical component magnetoresistance structure 511, the direction of the magnitude field vertical to the substrate surface is changed. Consequently, the resistance value of the magnetoresistance sensing unit that is composed of the horizontal component magnetoresistance structure 510 and the conductive structure 52 is changed, and the function of sensing the magnitude field vertical to the substrate surface is achieved. In other words, the vertical component magnetoresistance structure 511 is able to conduct the magnetic field. Moreover, an included angle between the vertical component magnetoresistance structure 511 and the horizontal component magnetoresistance structure 510 is 0˜90 degrees.

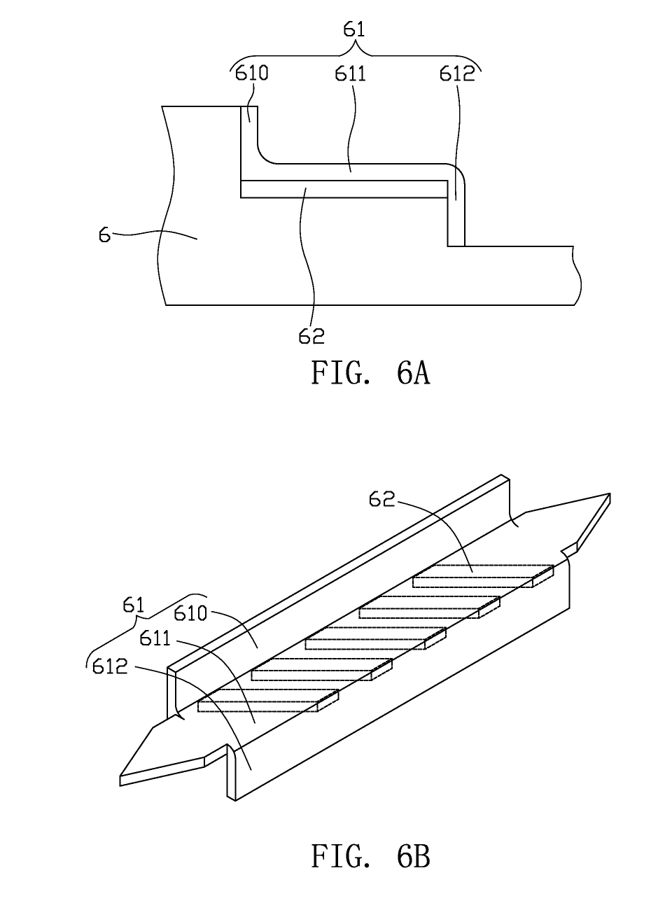

Please refer to FIGS. 6A and 6B, which schematically illustrate a magnetoresistance sensing device according to a second embodiment of the present invention. The magnetoresistance sensing device is capable of sensing the magnitude of a magnetic field in a direction vertical to the surface of the substrate in a three-dimensional space. FIG. 6A is a cross-sectional view of the magnetoresistance sensing device. As shown in FIG. 6A, the magnetoresistance sensing device is formed on a substrate 6, and comprises a three-dimensional magnetoresistance structure 61 and a conductive structure 62. The three-dimensional magnetoresistance structure 61 is composed of a first vertical component magnetoresistance structure 610, a horizontal component magnetoresistance structure 611 and a second vertical component magnetoresistance structure 612. The first vertical component magnetoresistance structure 610 is connected to a first edge of the horizontal component magnetoresistance structure 611. The second vertical component magnetoresistance structure 612 is connected to a second edge of the horizontal component magnetoresistance structure 611. In this embodiment, the substrate 6 has a stepped structure for accommodating the three-dimensional magnetoresistance structure 61. Especially, the first vertical component magnetoresistance structure 610 and the second vertical component magnetoresistance structure 612 are formed on two sidewalls of the stepped structure, respectively. The conductive structure 62 comprises a plurality of barber-pole conductors, which are disposed over or under the horizontal component magnetoresistance structure 611 at a specified angle. In this embodiment, the conductive structure 62 is disposed under the horizontal component magnetoresistance structure 611. In comparison with FIGS. 5A and 5B, the first vertical component magnetoresistance structure 610 and the second vertical component magnetoresistance structure 612 are respectively located at two opposite sides of the horizontal component magnetoresistance structure 611. Due to the first vertical component magnetoresistance structure 610 and the second vertical component magnetoresistance structure 612, the direction of the magnitude field vertical to the substrate surface is changed. Consequently, the resistance value of the magnetoresistance sensing unit that is composed of the horizontal component magnetoresistance structure 611 and the conductive structure 62 is changed, and the function of sensing the magnitude field vertical to the substrate surface is achieved. From the above discussion, as long as the function of changing direction of the magnitude field vertical to the substrate surface is achieve, the shape, size and number of the vertical component magnetoresistance structure may be varied.

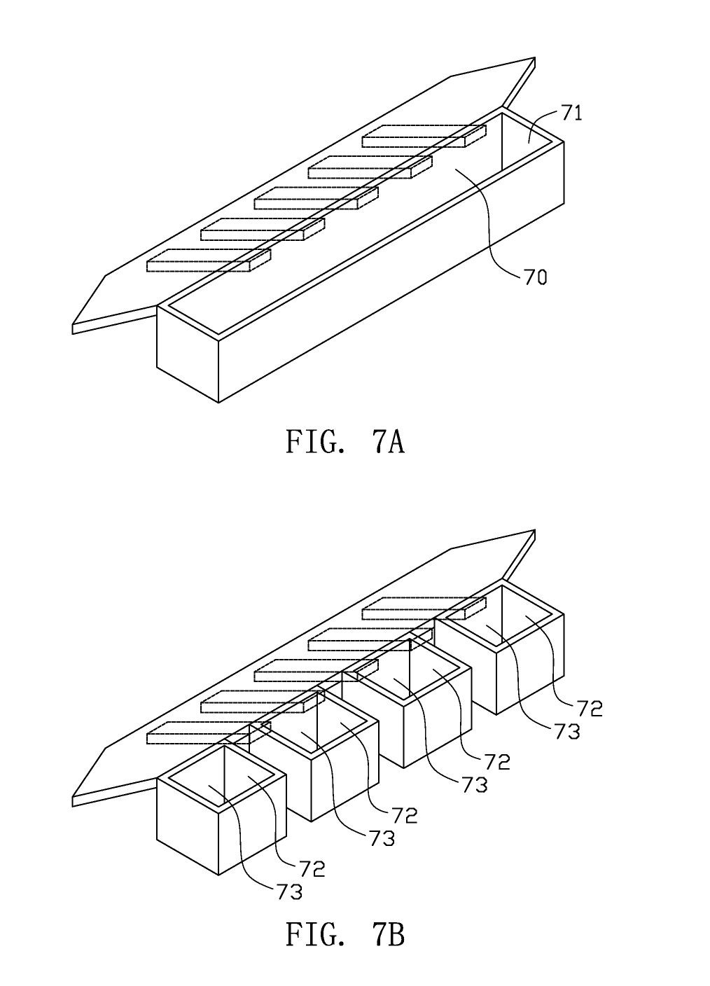

FIGS. 7A and 7B schematically illustrate two variant examples of the vertical component magnetoresistance structure used in the magnetoresistance sensing device of the present invention. As shown in FIG. 7A, the vertical component magnetoresistance structure 70 is formed on an inner wall of a trench structure 71. As shown in FIG. 7B, the vertical component magnetoresistance structure 72 is formed on the inner walls of several discontinuous trench structures 73. That is, numerous modifications of the vertical component magnetoresistance structure may be made while retaining the teachings of the invention. For example, the vertical component magnetoresistance structure may be formed on the outer walls of one or more raised blocks, which are located at a level higher than the horizontal component magnetoresistance structure.

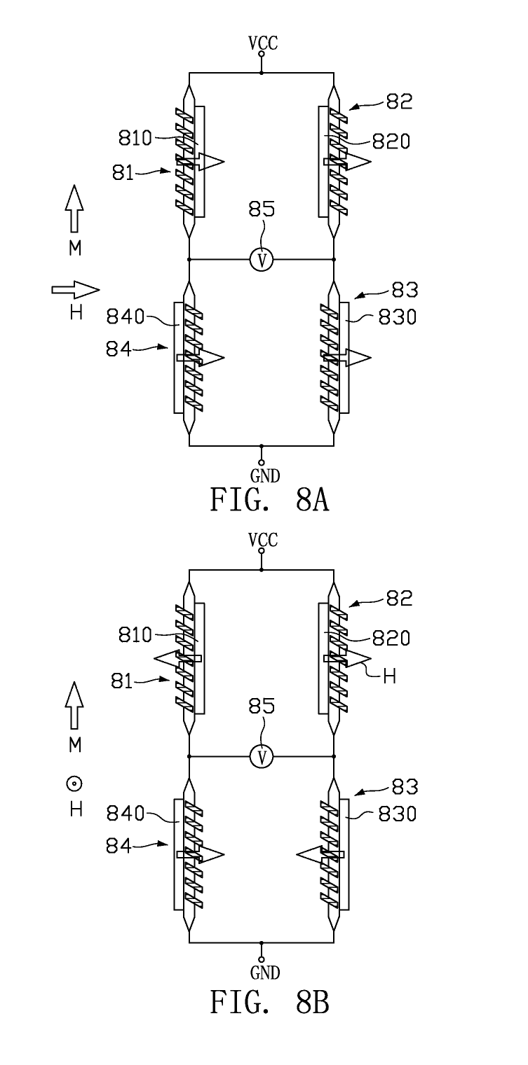

The present invention also provides a magnetoresistance sensor including several magnetoresistance sensing devices as described in the above embodiments. FIGS. 8A and 8B are schematic circuit diagrams illustrating a magnetoresistance sensor including four magnetoresistance sensing devices according to an embodiment of the present invention. As shown in FIGS. 8A and 8B, the magnetoresistance sensor comprises a first magnetoresistance sensing device 81, a second magnetoresistance sensing device 82, a third magnetoresistance sensing device 83 and a fourth magnetoresistance sensing device 84. The configurations of each of the magnetoresistance sensing devices 81, 82, 83 and 84 are identical to those of the magnetoresistance sensing device as shown in FIG. 5, and are not redundantly described herein. As previously described in FIG. 3, the lengthwise extending direction of the barber-pole conductors in first group is different from that in the second group. On the contrary, all conductive structures of the magnetoresistance sensing devices 81, 82, 83 and 84 of this embodiment have the same lengthwise extending direction. In a case that the four magnetoresistance sensing devices 81, 82, 83 and 84 have the same magnetization direction (e.g. in the direction indicated as the arrow M), the output voltage indicated in the voltmeter 85 of the Wheatstone bridge is not influenced by the magnetic field in the horizontal direction H. As shown in FIG. 8A, even if a horizontal magnetic field H exists in the space, the output voltage indicated in the voltmeter 85 is kept unchanged.

Moreover, each of the vertical component magnetoresistance structures 810, 820, 830 and 840 is located at a specified side of a corresponding one of the magnetoresistance sensing devices 81, 82, 83 and 84. In this embodiment, the vertical component magnetoresistance structures 810 and 830 are respectively located at the first sides of the first magnetoresistance sensing device 81 and the third magnetoresistance sensing device 83, and the vertical component magnetoresistance structures 820 and 840 are respectively located at the second sides of the second magnetoresistance sensing device 82 and the fourth magnetoresistance sensing device 84. The magnetic field vertical to the substrate surface is received by the vertical component magnetoresistance structures. The magnetic flux conducting structures are capable of changing the direction of the vertical magnetic field to be consistent with the substrate surface. This horizontal magnetic field is conducted to the horizontal component magnetoresistance structure that is connected with the vertical component magnetoresistance structure. Consequently, in response to the magnitude and direction of the vertical magnetic field ⊙ in the space, each of the magnetoresistance sensing devices 81, 82, 83 and 84 results in a change of an electrical resistance. Under this circumstance, if the vertical magnetic field ⊙ exists in the space, the output voltage indicated in the voltmeter 85 will be correspondingly changed (see FIG. 8B).

Of course, the initial magnetization direction, the orientation of the conductive structure, the location of the vertical component magnetoresistance structure and the combination thereof may be altered while retaining the teachings of the invention. That is, if a horizontal magnetic field H exists in the space, the output voltage indicated in the voltmeter is kept unchanged. Whereas, if a vertical magnetic field exists in the space, the output voltage indicated in the voltmeter is changed. In other words, the above descriptions are presented herein for purpose of illustration and description only.

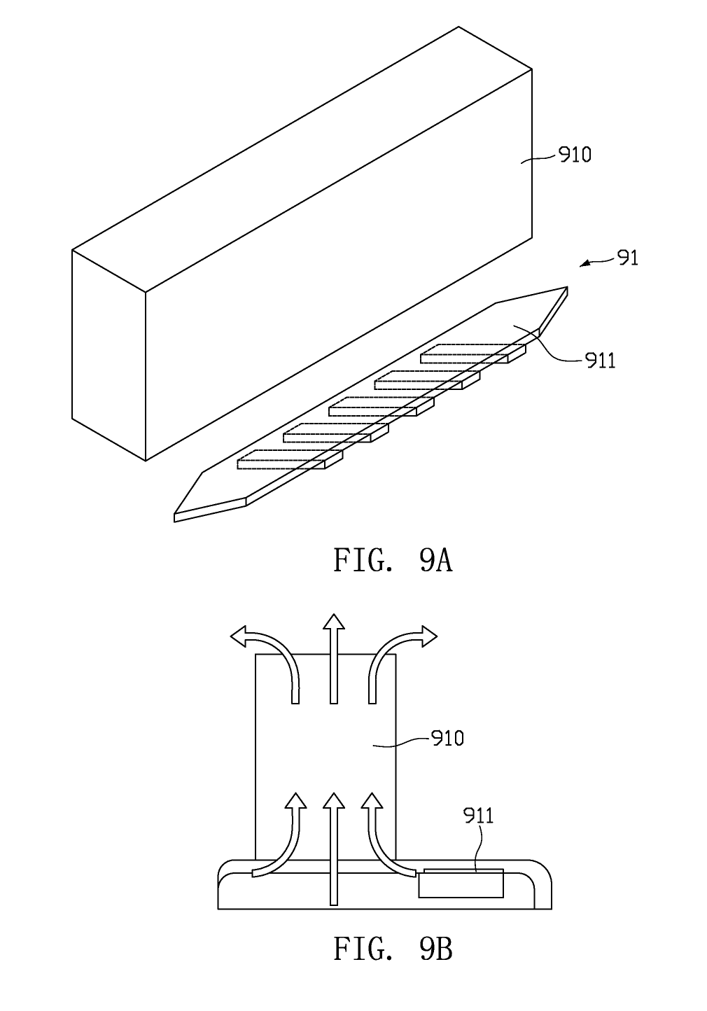

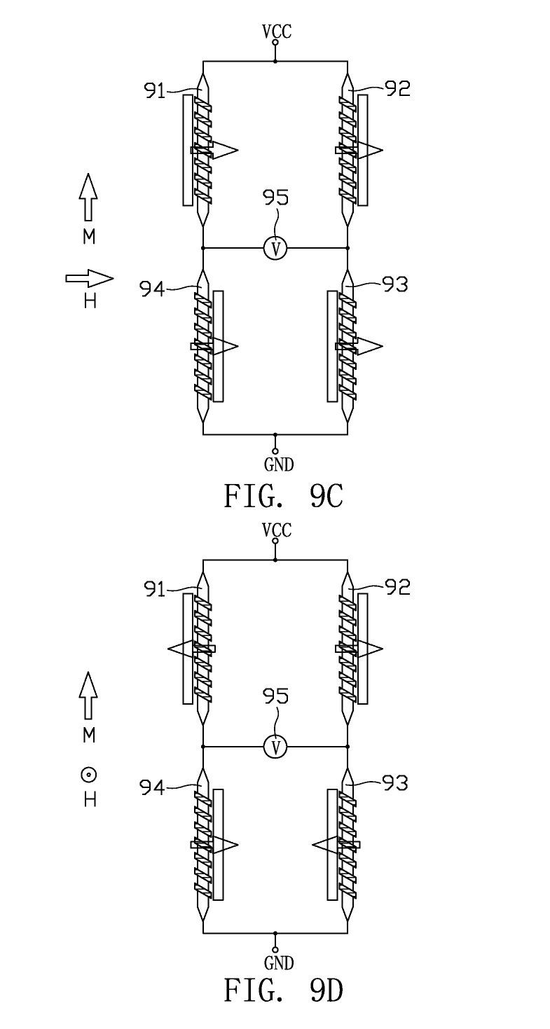

Please refer to FIGS. 9A and 9B, which schematically illustrate a magnetoresistance sensing device according to a third embodiment of the present invention. FIG. 9A is schematic perspective view of the magnetoresistance sensing device. As shown in FIG. 9A, the magnetoresistance sensing device 91 comprises a magnetic flux conducting structure 910 and a horizontal component magnetoresistance structure 911. FIG. 9B is a schematic cross-sectional view of the magnetoresistance sensing device as shown in FIG. 9A. The magnetic flux conducting structure 910 is made of a magnetic material. Moreover, the magnetic flux conducting structure 910 is used for changing the distribution of the magnetic field in the space. In other words, the magnetic flux conducting structure 910 is used as a magnetic flux concentrator for concentrating the magnetic flux, thereby changing the direction of a portion of the magnetic field in the space. In such way, the magnetic flux conducting structure 910 and the horizontal component magnetoresistance structure 911 are capable of sensing the horizontal component of the vertical magnetic field in the space after the direction of a portion of the vertical magnetic field is changed. The configurations of the horizontal component magnetoresistance structure 911 are similar to those of the horizontal component magnetoresistance structure as shown in FIG. 2, FIG. 5 or FIG. 6, and are not redundantly described herein.

FIGS. 9C and 9D are schematic circuit diagrams illustrating a magnetoresistance sensor including four magnetoresistance sensing devices as shown in FIGS. 9A and 9B. In this embodiment, the magnetoresistance sensor comprises a first magnetoresistance sensing device 91, a second magnetoresistance sensing device 92, a third magnetoresistance sensing device 93 and a fourth magnetoresistance sensing device 94. The configurations of each of the magnetoresistance sensing devices 91, 92, 93 and 94 are identical to those of the magnetoresistance sensing device as shown in 9A and 9B, and are not redundantly described herein. It is noted that the four magnetoresistance sensing devices 91, 92, 93 and 94 have the same magnetization direction (e.g. in the direction indicated as the arrow M). Moreover, all conductive structures of the magnetoresistance sensing devices 91, 92, 93 and 94 of this embodiment have the same lengthwise extending direction. Consequently, the horizontal magnetic field is the space can be completely sheltered. That is, the output voltage indicated in the voltmeter 95 of the Wheatstone bridge is not influenced by the horizontal magnetic field H. As shown in FIG. 9C, even if a horizontal magnetic field H exists in the space, the output voltage indicated in the voltmeter 95 is kept unchanged.

Moreover, each of the magnetic flux conducting structures 910, 920, 930 and 940 is located at a specified side of a corresponding one of the magnetoresistance sensing devices 91, 92, 93 and 94. In this embodiment, the magnetic flux conducting structures 910 and 930 are respectively located at the first sides of the first magnetoresistance sensing device 91 and the third magnetoresistance sensing device 93, and the magnetic flux conducting structures 920 and 940 are respectively located at the second sides of the second magnetoresistance sensing device 92 and the fourth magnetoresistance sensing device 94 for receiving the magnetic field in the direction vertical to the substrate surface. The magnetic field vertical to the substrate surface is received by the magnetic flux conducting structures. The magnetic flux conducting structures are capable of changing the direction of the vertical magnetic field to be horizontal to the substrate surface. This horizontal magnetic field is conducted to the horizontal component magnetoresistance structures 911, 921, 931 and 941. Consequently, in response to the magnitude and direction of the vertical magnetic field ⊙ in the space, each of the magnetoresistance sensing devices 91, 92, 93 and 94 results in a change of an electrical resistance. Under this circumstance, if the vertical magnetic field ⊙ exists in the space, the output voltage indicated in the voltmeter 95 will be correspondingly changed (see FIG. 9D).

Of course, the initial magnetization direction, the orientation of the conductive structure, the location of the vertical component magnetoresistance structure and the combination thereof may be altered while retaining the teachings of the invention. That is, if a horizontal magnetic field H exists in the space, the output voltage indicated in the voltmeter is kept unchanged. Whereas, if a vertical magnetic field exists in the space, the output voltage indicated in the voltmeter is changed. In other words, the above descriptions are presented herein for purpose of illustration and description only.

For saving the layout area, one magnetic flux conducting structures is shared between two magnetoresistance sensing devices. Take the architecture as shown in FIG. 9D for example. A magnetic flux conducting structures is shared between the first magnetoresistance sensing device 91 and the second magnetoresistance sensing device 92, and another magnetic flux conducting structures is shared between the third magnetoresistance sensing device 93 and the fourth magnetoresistance sensing device 94. The magnetic flux conducting structure is made of a magnetic material. According to the practical requirements, the shape and size of the magnetic flux conducting structure may be varied.

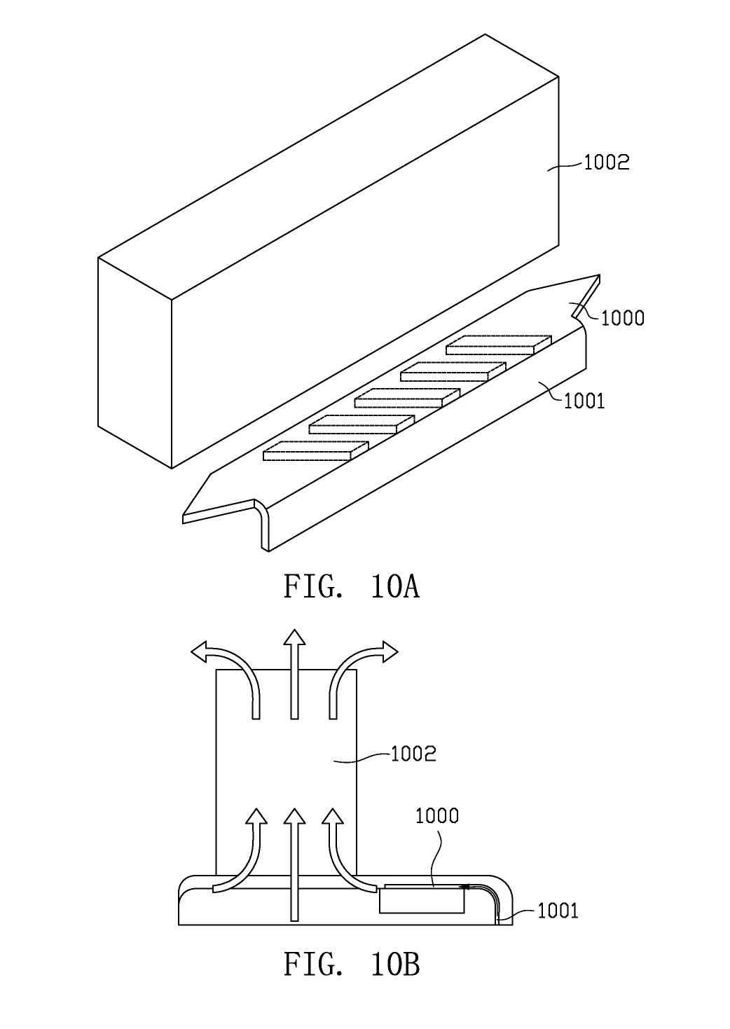

The present invention further provides a magnetoresistance sensing device and a magnetoresistance sensor including the magnetoresistance sensing device. FIGS. 10A and 10B schematically illustrate a magnetoresistance sensing device according to a fourth embodiment of the present invention. This embodiment is a combination of the above two embodiments. In this embodiment, the magnetoresistance sensing device comprises a horizontal component magnetoresistance structure 1000, a vertical component magnetoresistance structure 1001 and a magnetic flux conducting structure 1002. The vertical component magnetoresistance structure 1001 is formed on an inner wall of the trench in the substrate. Moreover, the vertical component magnetoresistance structure 1001 and the magnetic flux conducting structure 1002 are located at two opposite sides of the horizontal component magnetoresistance structure 1000. In such way, the sensitivity of sensing the vertical magnetic field is enhanced.

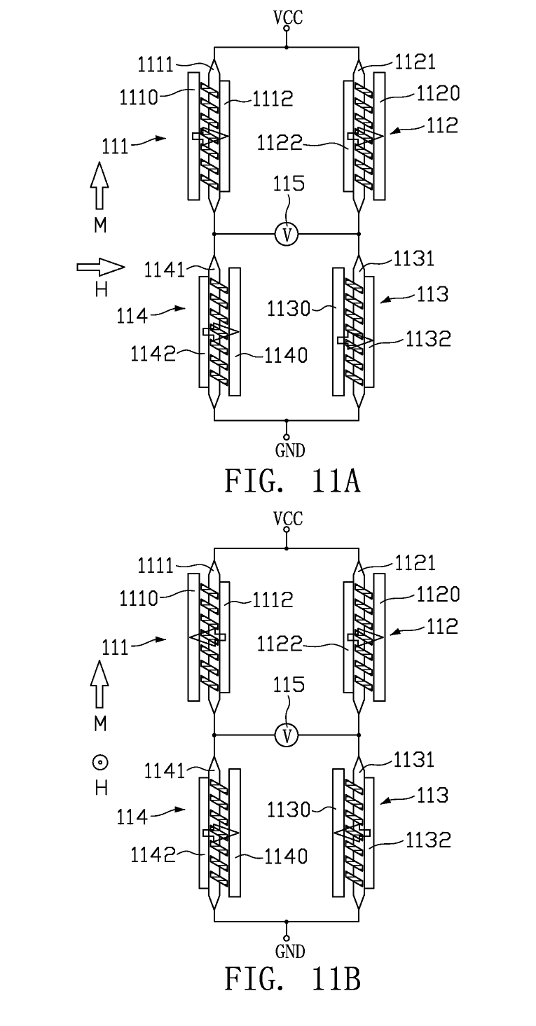

FIGS. 11A and 11B are schematic circuit diagrams illustrating a magnetoresistance sensor including four magnetoresistance sensing devices as shown in FIGS. 10A and 10B. In this embodiment, the magnetoresistance sensor comprises a first magnetoresistance sensing device 111, a second magnetoresistance sensing device 112, a third magnetoresistance sensing device 113 and a fourth magnetoresistance sensing device 114. The four magnetoresistance sensing devices 111, 112, 113 and 114 have the same magnetization direction (e.g. in the direction indicated as the arrow M). Moreover, all conductive structures of the magnetoresistance sensing devices 111, 112, 113 and 114 have the same lengthwise extending direction. Consequently, the horizontal magnetic field is the space can be completely sheltered. That is, the output voltage indicated in the voltmeter 115 of the Wheatstone bridge is not influenced by the horizontal magnetic field H. As shown in FIG. 11A, even if a horizontal magnetic field H exists in the space, the output voltage indicated in the voltmeter 115 is kept unchanged.

Moreover, the magnetic flux conducting structures 1110, 1120, 1130 and 1140 and the vertical component magnetoresistance structures 1112, 1122, 1132 and 1142 are located at bilateral sides of the horizontal component magnetoresistance structures 1111, 1121, 1131 and 1141 of respective magnetoresistance sensing devices 111, 112, 113 and 114. The first magnetoresistance sensing device 111 and the third magnetoresistance sensing device 113 have the same configurations, wherein the magnetic flux conducting structure is located at the first side and the vertical component magnetoresistance structure is located at the second side. The second magnetoresistance sensing device 112 and the fourth magnetoresistance sensing device 114 have the same configurations, wherein the magnetic flux conducting structure is located at the second side and the vertical component magnetoresistance structure is located at the first side. The magnetic field vertical to the substrate surface is received by the magnetic flux conducting structures and the vertical component magnetoresistance structure. The magnetic flux conducting structures and the vertical component magnetoresistance structure are capable of changing the direction of the vertical magnetic field to be horizontal to the substrate surface. This horizontal magnetic field is conducted to the horizontal component magnetoresistance structures 1111, 1121, 1131 and 1141. Consequently, in response to the magnitude and direction of the vertical magnetic field ⊙ in the space, each of these magnetoresistance sensing devices results in a change of an electrical resistance. Under this circumstance, if the vertical magnetic field ⊙ exists in the space, the output voltage indicated in the voltmeter 115 will be correspondingly changed (see FIG. 11B).

Of course, the initial magnetization direction, the orientation of the conductive structure, the location of the vertical component magnetoresistance structure and the combination thereof may be altered while retaining the teachings of the invention. That is, if a horizontal magnetic field H exists in the space, the output voltage indicated in the voltmeter is kept unchanged. Whereas, if a vertical magnetic field exists in the space, the output voltage indicated in the voltmeter is changed. In other words, the above descriptions are presented herein for purpose of illustration and description only.

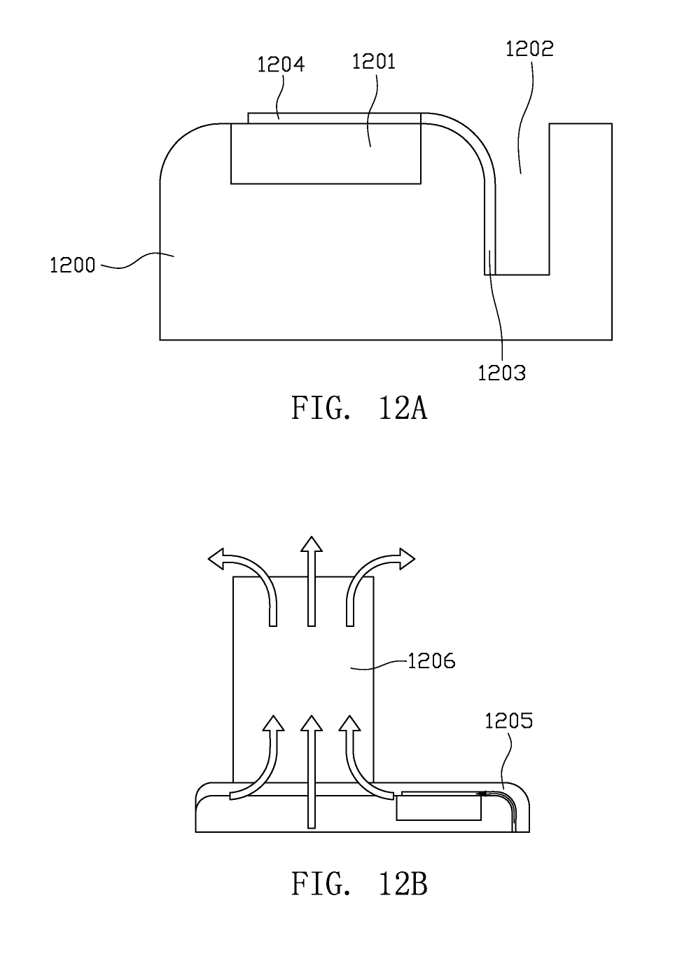

The magnetoresistance sensing device of the present invention may be produced by a semiconductor manufacturing method. FIGS. 12A and 12B schematically illustrate a semiconductor manufacturing method of the magnetoresistance sensing device according to an embodiment of the present invention. As shown in FIG. 12A, a conductive structure 1201 is formed on the substrate 1200. Then, a chemical mechanical polishing process is performed to flatten the conductive structure 1201. Then, a photolithography and etching process is performed to form a trench structure 1202 at the position beside the conductive structure 1201. Then, a magnetic film is grown. Then, another photolithography and etching process is performed to simultaneously define a three-dimensional component magnetoresistance structure including a vertical component magnetoresistance structure 1203 and a horizontal component magnetoresistance structure 1204. Then, as shown in FIG. 12B, after a passivation layer 1205 is formed over the resulting structure of FIG. 12A, a magnetic flux conducting structure is formed. Meanwhile, the magnetoresistance sensing device is produced.

From the above description, the present invention provides a magnetoresistance sensing device for sensing a magnetic field in the direction vertical to the substrate surface. The magnetoresistance sensing device of the present invention and the conventional magnetoresistance sensing device for sensing the horizontal magnetic field may be combined as an integrated magnetoresistance sensing device for sensing the magnetic field in the three-dimensional space. Moreover, the magnetoresistance sensing device of the present invention and the conventional magnetoresistance sensing device for sensing the horizontal magnetic field are integrated into the same chip (or substrate) to define the integrated magnetoresistance sensing device by the same semiconductor manufacturing process. In comparison with the conventional technique of combining at least two orthogonal substrates, the present invention is more advantageous because the angular misalignment between two substrates and additional circuit board wiring mechanism are no longer taken into consideration and the packaging chip is thinner. In addition, the method of fabricating the integrated magnetoresistance sensing device of the present invention is cost-effective.

In the above embodiments, the vertical component magnetoresistance structure of the magnetoresistance sensing device is served as a magnetic field adjusting unit. The vertical component magnetoresistance structure is connected with the horizontal component magnetoresistance structure to constitute a three-dimensional magnetoresistance structure. In some embodiments, the vertical component magnetoresistance structure may be separated from the horizontal component magnetoresistance structure.

From the above description, the magnetoresistance sensing device of the present invention comprises a three-dimensional magnetoresistance structure (including the vertical component magnetoresistance structure), optionally a magnetic flux conducting structure, and a conductive structure. The magnetic flux conducting structure or the vertical component magnetoresistance structure is able to change a direction of the vertical magnetic field to be consistent with the horizontal magnetic field. Consequently, the magnetoresistance sensing device results in a change of an electrical resistance. Moreover, four magnetoresistance sensing devices can be arranged in a Wheatstone bridge to individually detect the vertical magnetic field. In the above embodiment, each of the magnetoresistance structure is an anisotropic magnetoresistance (AMR) structure, a giant magnetoresistance (GMR) structure, a tunneling magnetoresistance (TMR) structure, or a combination thereof.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A magnetoresistance sensing device, comprising:
a substrate;
a magnetoresistance sensing unit formed over the substrate, wherein in response to a first external magnetic field horizontal to a surface of the substrate, the magnetoresistance sensing unit results in a change of an electrical resistance; and
a magnetic field adjusting unit formed over the substrate for changing a direction of a second external magnetic field vertical to the surface of the substrate to be consistent with the first external magnetic field, so that the magnetoresistance sensing unit results in a change of the electrical resistance in response to the second external magnetic field.

2. The magnetoresistance sensing device according to claim 1, wherein the magnetoresistance sensing unit comprises:
a horizontal component magnetoresistance structure formed over the substrate; and
a conductive structure formed over the substrate for changing a direction of a current flowing through the horizontal component magnetoresistance structure, so that the horizontal component magnetoresistance structure results in a change of the electrical resistance in response to the first external magnetic field, wherein an angle between a lengthwise extending direction of the conductive structure and a lengthwise extending direction of the horizontal component magnetoresistance structure is greater than 0 degree and smaller than 90 degrees.

3. The magnetoresistance sensing device according to claim 2, wherein the conductive structure is disposed over the conductive structure.

4. The magnetoresistance sensing device according to claim 2, wherein the conductive structure is disposed under the conductive structure.

5. The magnetoresistance sensing device according to claim 2, wherein the magnetic field adjusting unit is a vertical component magnetoresistance structure, wherein the horizontal component magnetoresistance structure and the vertical component magnetoresistance structure are collaboratively defined as a three-dimensional magnetoresistance structure.

6. The magnetoresistance sensing device according to claim 5, wherein the vertical component magnetoresistance structure is formed on inner walls of one or more trench structures in the substrate.

7. The magnetoresistance sensing device according to claim 5, wherein the vertical component magnetoresistance structure is formed on outer walls of one or more raised structures on the substrate.

8. The magnetoresistance sensing device according to claim 5, wherein the vertical component magnetoresistance structure is formed on two sidewalls of a stepped structure of the substrate.

9. The magnetoresistance sensing device according to claim 1, wherein the magnetic field adjusting unit is a magnetic flux conducting structure for changing magnetic field distribution in the space, thereby concentrating a magnetic flux of the second external magnetic field and guiding the magnetic flux in a direction consistent with the first external magnetic field.

10. A magnetoresistance sensor comprising four magnetoresistance sensing devices, each having the same structure as the magnetoresistance sensing device according to claim 1, wherein the four magnetoresistance sensing devices are arranged in a Wheatstone bridge and comprise a first magnetoresistance sensing device, a second magnetoresistance sensing device, a third magnetoresistance sensing device and a fourth magnetoresistance sensing device, wherein each of the second magnetoresistance sensing device and the fourth magnetoresistance sensing device is connected to both of the first magnetoresistance sensing device and the third magnetoresistance sensing device, wherein an output voltage of the Wheatstone bridge is not altered as the first external magnetic field is changed, but the output voltage of the Wheatstone bridge is altered as the second external magnetic field is changed.
